(19) United States
(12) Patent Application Publication
(10) Pub. No.: US 2012/0325295 A1
(43) Pub. Date: Dec. 27, 2012

(54) Photoelectric device and a method for manufacturing a transparent electrode

(75) Inventors: Frank Sauberlich, Dunningen - Seedorf (DE); Bernd Stannowski, Berlin (DE); Tobias Wendelmuth, Striegistal (DE); Volker Sittinger, Braunschweig (DE); Bernd Szyszka, Braunschweig (DE)

(73) Assignees: Fraunhofer-Gesellschaft zur Foerderung der Angewandten Forschung E. V., Muenchen (DE); Schueco TF GmbH & Co. KG, Bielefeld (DE)

(21) Appl. No.: 13/460,499

(22) Filed: Apr. 30, 2012

(30) Foreign Application Priority Data
Oct. 30, 2009 (DE) 10 2009 051 345.0

(51) Int. Cl. H01L 31/0232; H01L 31/04

(52) U.S. Cl. 136/252; 427/74; 257/E31.126

(57) ABSTRACT

An arrangement includes a transparent substrate, at least one transparent electrically conductive layer on the substrate. At least one photoelectric device for converting radiation energy into electrical energy can be arranged on the at least one transparent electrically conductive layer. The at least one transparent electrically conductive layer includes at least one first transparent electrically conductive layer and at least one second transparent electrically conductive layer.

This patent application is a continuation of PCT/EP2010/063634, filed Sep. 16, 2010, which claims the priority of German patent application 10 2009 051 345.0, filed Oct. 30, 2009, each of which is incorporated herein by reference in its entirety.

### TECHNICAL FIELD

The invention relates to an arrangement comprising a transparent electrically conductive layer, an arrangement comprising at least one photoelectric device and at least one transparent electrically conductive layer, and to a method for producing a transparent electrode.

### BACKGROUND

Photoelectric devices, which are also called solar cells, can convert at least parts of the solar radiation into electrical energy. Photoelectric devices have one or a plurality of pn junctions. An i-layer is arranged between the p-layer and the n-layer. The p-layer is a positively doped layer, the n-layer is a negatively doped layer and the i-layer is a substantially intrinsic semiconductor layer. The p-layer and the n-layer principally serve to generate a drift field in the photoelectric arrangement. By means of the photoelectric effect, a radiation energy contained in the light is converted into electrical energy. Photoelectric arrangements or solar cells can be interconnected to form photovoltaic modules in which a plurality of photoelectric arrangements are connected in series.

Photoelectric arrangements comprise, for example, microcrystalline silicon layers, amorphous silicon layers, polycrystalline silicon layers or other semiconductors. In order to make electrical contact with the front side of the semiconductor layers, transparent conductive layers (for example TCO—transparent conductive oxide) are deposited onto the p-layer and the n-layer. By means of a structured and roughened surface of these contact layers, it is possible to scatter incident solar light in this layer and thereby to convert a larger proportion of the radiation energy into electrical energy. This surface structuring can be produced by means of an etching step, for example.

### SUMMARY OF THE INVENTION

It is desirable to specify an arrangement and a system for producing a transparent electrode in order to make possible an electrode that is improved with regard to the etching properties.

An arrangement comprises a transparent substrate and at least one transparent electrically conductive layer on the substrate. The at least one transparent electrically conductive layer comprises at least one first transparent electrically conductive layer and at least one second transparent electrically conductive layer.

In one embodiment, the at least one first transparent electrically conductive layer and the at least one second transparent electrically conductive layer each have at least one property. In one embodiment, the at least one property of the at least one second transparent electrically conductive layer is dependent on the at least one property of the at least one first transparent electrically conductive layer.

The at least one transparent electrically conductive layer comprises at least two transparent electrically conductive layers. In exemplary embodiments, the at least one transparent electrically conductive layer comprises three transparent electrically conductive layers; it can also comprise more layers, for example four or more transparent electrically conductive layers. Properties of the transparent electrically conductive layer can be set by properties of the first transparent electrically conductive layer and properties of the second transparent electrically conductive layer. At least one property of the transparent electrically conductive layer is dependent on the at least one property of the first transparent electrically conductive layer and on the at least one property of the second transparent electrically conductive layer. Thus, in one embodiment, the transparent electrically conductive layer has properties depending on the first and the second electrically conductive layer which are not able to be realized, or are able to be realized at least with more difficulty, by means of a single-layered construction. If the transparent electrically conductive layer comprises more than two layers, then the properties of the transparent electrically conductive layer are dependent on the more than two layers. The at least one property of one of the electrically conductive layers of the plurality of electrically conductive layers in each case influences the at least one property of the other electrically conductive layers of the plurality of electrically conductive layers.

The at least one property of the respective layers comprises, for example, at least one of crystallinity, orientation and termination of the respective layer. Accordingly, in one embodiment, the crystallinity, orientation and/or termination of the second transparent electrically conductive layer are/is influenced by the crystallinity, orientation and/or termination of the first transparent electrically conductive layer. At least the morphology and/or the structure of the second transparent electrically conductive layer are/is likewise influenced by the influencing of the crystallinity, orientation and/or termination. Consequently, the surface structurability, the electrical conductivity and/or the optical transmissivity of the second electrically conductive layer are/is dependent on the surface structurability, the electrical conductivity and/or the optical transmissivity of the first transparent electrically conductive layer.

In one embodiment, the at least one first transparent electrically conductive layer and the at least one second transparent electrically conductive layer comprise a transparent electrically conductive oxide, in particular in each case zinc oxide or tin oxide. As a result, the desired properties for the transparent electrically conductive layer with regard to surface structurability, optical transmissivity and/or electrical conductivity can be realized as well as possible.

In one embodiment, the at least one first transparent electrically conductive layer has a thickness in the main direction of the incident radiation of between 30 nanometers±10% and 400 nanometers±10%. In one embodiment, the at least one second transparent electrically conductive layer has a thickness of more than 200 nanometers in the main direction of the incident radiation.

A further arrangement comprises such an arrangement. A photoelectric device for converting radiation energy into electrical energy is arranged on the transparent electrically conductive layer of the arrangement. In the main incidence direction of the radiation to be converted during operation, there are arranged firstly the transparent substrate, thereupon the transparent electrically conductive layer and thereupon the at least one photoelectric device.

A method for producing a transparent electrode on a transparent substrate comprises providing the transparent substrate. A first transparent electrically conductive layer is deposited onto the transparent substrate. The first transparent electrically conductive layer has a property. A second transparent electrically conductive layer is deposited onto the first transparent electrically conductive layer. The second transparent electrically conductive layer has a property. As a result of the second transparent electrically conductive layer being deposited on the first transparent electrically conductive layer, the property of the second transparent electrically conductive layer is dependent on the property of the first transparent electrically conductive layer.

In particular, in one embodiment, as a result of the second transparent electrically conductive layer being deposited onto the first transparent electrically conductive layer, at least the crystallinity, orientation and/or termination of the second transparent electrically conductive layer are/is dependent on the first transparent electrically conductive layer. In one exemplary embodiment, the first transparent electrically conductive layer is deposited with process parameters which result in properties, for example with regard to the surface structurability, the electrical conductivity and/or the optical transmissivity, of the first transparent electrically conductive layer which are conventionally undesirable for transparent electrically conductive layers that are used as an electrode. These properties of the first transparent electrically conductive layer influence the properties, for example with regard to the surface structurability, the electrical conductivity and/or the optical transmissivity, of the second transparent electrically conductive layer in such a way that the second transparent electrically conductive layer has a comparatively good surface structurability.

The surface structurability encompasses the fact, in particular, that by means of a structuring, for example an etching, it is possible to produce a roughness that is as homogeneous as possible, a good homogeneity and/or a uniformly distributed thickness in each case relative to the substrate surface. Furthermore, a layer having better surface structurability has a better light scattering after the structuring and the coupling of the incident radiation into the photoelectric device arranged on the transparent electrically conductive layer is correspondingly increased. Furthermore, light scattered better has on average a longer path in the photoelectric device, such that a higher absorption probability and thus a higher effectiveness are achieved.

The deposition of the first and of the second transparent electrically conductive layer can comprise a deposition of zinc oxide, tin oxide or some other transparent electrically conductive oxide. Thus, the property of the transparent electrode with regard to surface structurability can be adapted as well as possible.

In one embodiment the method comprises depositing the first transparent electrically conductive layer at a first substrate temperature and depositing the second transparent electrically conductive layer at a second substrate temperature, wherein the first substrate temperature is less than the second substrate temperature.

In one embodiment, the method comprises depositing the first transparent electrically conductive layer at a first power density and depositing the second transparent electrically conductive layer at a second power density, wherein the first power density is less than the second power density.

In particular, the first transparent electrically conductive layer is deposited with parameters, for example temperature and/or power density, which conventionally do not lead to a comparatively good surface structurability. The second transparent electrically conductive layer is deposited with parameters, such that the second transparent electrically conductive layer and thus the transparent electrically conductive layer, by virtue of the dependence on the first transparent electrically conductive layer, has a comparatively good surface structurability. The transparent electrically conductive layer has a better surface structurability than the first transparent electrically conductive layer taken by itself.

### BRIEF DESCRIPTION OF THE DRAWINGS

Further features, advantages and developments are evident from the examples explained below in conjunction with FIGS. 1 to 3.

FIG. 1 shows a schematic illustration of an arrangement in accordance with one embodiment;

FIGS. 2A to 2C show a schematic illustration of a device for various method steps in accordance with one embodiment; and

FIG. 3 shows a schematic illustration of an arrangement in accordance with one embodiment.

Elements that are identical, of identical type and act identically are provided with the same reference signs in the figures.

### DETAILED DESCRIPTION OF ILLUSTRATIVE EMBODIMENTS

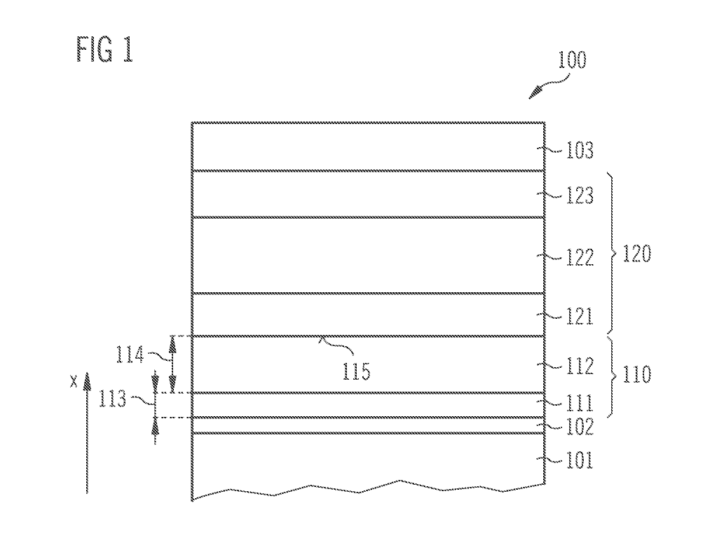

FIG. 1 shows a schematic cross section through an arrangement 100 for converting radiation energy into electrical energy. The arrangement 100 comprises, in the main direction of the radiation incident during operation, a substrate 101 and a passivation layer 102 arranged thereon. A transparent electrically conductive layer 110 is arranged on the passivation layer. A photoelectric device 120 is arranged on the transparent electrically conductive layer 110, in which device radiation energy can be converted into electrical energy by the photoelectric effect. A rear contact layer 103 is arranged on the photoelectric device.

The substrate 101 is as transparent as possible to sunlight. In particular, the substrate 101 is particularly transmissive to light in the visible spectrum and in the infrared range and has a transparency of greater than 85 percent in a wavelength range of 400 nanometers to 1200 nanometers. The substrate comprises, for example, glass, in particular low-iron flat glass, silicate glass or rolled glass. The substrate 101 is designed to carry the layer stack arranged on the substrate 101.

In a further embodiment, the layer stack is deposited on a flexible substrate comprising, for example, aluminum or steel. The layer stack is coupled to a transparent substrate on the opposite side relative to the flexible substrate and the flexible substrate is detached from the layer stack and removed.

In the main incidence direction of the light incident during operation, this direction corresponding to the X-direction in FIG. 1, the passivation layer 102 is arranged on the substrate 101. In a further embodiment, the passivation layer 102 can be dispensed with, such that the transparent electrically conductive layer 110 is arranged directly on the substrate 101 and touches the latter. The passivation layer 102 comprises one of transparent oxide and transparent nitride, for example silicon oxynitride, zinc oxide, titanium oxide or aluminum oxide and reduces as a barrier a particle or molecular movement between the substrate 101 and the transparent electrically conductive layer 110.

The transparent electrically conductive layer 110 comprises a first transparent electrically conductive layer 111 and a second transparent electrically conductive layer 112. In the X-direction, the first transparent electrically conductive layer is arranged on the passivation layer 102 and the second transparent electrically conductive layer 112 is arranged on the first electrically conductive layer 111. In particular, the first transparent electrically conductive layer 111 and the second transparent electrically conductive layer 112 are arranged in direct contact with one another. The first electrically conductive layer 111 extends as flatly and uniformly as possible over the substrate 101. The second electrically conductive layer 112 extends as flatly and uniformly as possible over the first electrically conductive layer 111.

The first transparent electrically conductive layer 111 and the second transparent electrically conductive layer 112, which jointly form the transparent electrically conductive layer 110, form a transparent front-side electrode for making electrical contact with the photoelectric device 120. Via the transparent electrically conductive layer 110, electrical voltage or electric current can be conducted away from the photoelectric device 120.

The photoelectric device 120 is arranged in the X-direction on the second transparent electrically conductive layer 112. The photoelectric device 120 comprises a p-doped layer 121 and an n-doped layer 123 and also an intrinsic layer 122 arranged between the layer 121 and the layer 123. The p-doped layer 121 is arranged in the X-direction on the second transparent electrically conductive layer 112. In a further embodiment, the n-doped layer is arranged on the second transparent electrically conductive layer 112. The intrinsic layer 122 is designed to absorb and photoelectrically convert light. The photoelectric device 120 is designed to absorb principally light in a wavelength range of 400 to 1200 nanometers.

In the X-direction, the rear-side contact 103 is arranged on the photoelectric arrangement 120, said rear-side contact being designed to carry current or voltage away from the photoelectric arrangement 120. In a further exemplary embodiment, at least one further photoelectric arrangement comparable to the photoelectric arrangement 120 is arranged between the transparent electrically conductive layer 110 and the rear-side contact 103.

The transparent electrically conductive layer 110 comprises zinc oxide. The first transparent electrically conductive layer 111 and the second transparent electrically conductive layer 112 likewise comprise zinc oxide in each case. A surface 115 of the second transparent electrically conductive layer 112, said surface facing away from the substrate 101, has a rough texture formed as homogeneously as possible, such that this surface has a good scattering capability for the incident light in a wavelength range of 400 nanometers to 1200 nanometers. It is thereby possible to increase the effectiveness of the photoelectric arrangement 120 since the path of the incident radiation through the photoelectric device 120 is lengthened on average, the incident light is better coupled into the photoelectric device 120 and a higher absorption probability of the incident radiation is achieved.

Moreover, the transparent electrically conductive layer 110 has the best possible optical transmissivity and the best possible electrical conductivity. The first transparent electrically conductive layer 111 taken by itself has different properties with regard to the surface structurability, that is to say the possibility of forming a homogeneous rough texture on the surface, the optical transmissivity and the electrical conductivity than the second transparent electrically conductive layer 112 if the layers 111 and 112 are taken into consideration by themselves in each case separately from one another. The first transparent electrically conductive layer 111 has a different crystallinity, a different orientation and/or a different termination with respect to the second transparent electrically conductive layer 112. The first transparent electrically conductive layer 111 has a different morphology and structure with respect to the second transparent electrically conductive layer 112.

The second transparent electrically conductive layer 112 is optically more transparent and has a better conductivity than the first transparent electrically conductive layer 111 if the layers are taken into consideration by themselves in each case separately from one another. The first transparent electrically conductive layer 111 has properties, such that the first transparent electrically conductive layer 111 taken by itself could be used only inadequately as a front electrode. The crystallinity, the orientation and/or the termination of the second transparent electrically conductive layer 112 are/is formed because the second transparent electrically conductive layer 112 is arranged on the first transparent electrically conductive layer 111. The second transparent electrically conductive layer 112 taken by itself, given the same production process, would form a different crystallinity, orientation and/or termination than in the case of arrangement on the first transparent electrically conductive layer 111.

The surface structurability of the electrically conductive layer 110 corresponds to the surface structurability of the second transparent electrically conductive layer 112 depending on the first transparent electrically conductive layer 111. A good surface structurability encompasses the fact, in particular, that by means of etching, for example using dilute hydrochloric acid, it is possible to form a roughness that is as homogeneous as possible relative to the substrate surface, which leads to an improved light scattering, on the surface 115 of the transparent electrically conductive layer 110.

A thickness 113 of the first transparent electrically conductive layer 111 in the X-direction is greater than approximately 30 nanometers and less than approximately 400 nanometers. In particular, the thickness 113 is less than 100 nanometers, preferably less than approximately 50 nanometers and for example 40 nanometers±10%.

A thickness 114 of the second transparent electrically conductive layer 112 in the X-direction is greater than approximately 200 nanometers and less than approximately 1000 nanometers. In particular, the thickness 114 is greater than approximately 600 nanometers and less than approximately 900 nanometers, for example 800 nanometers±10%. The thickness 114 of the second transparent electrically conductive layer is dependent on the best possible optical transmissivity and electrical conductivity.

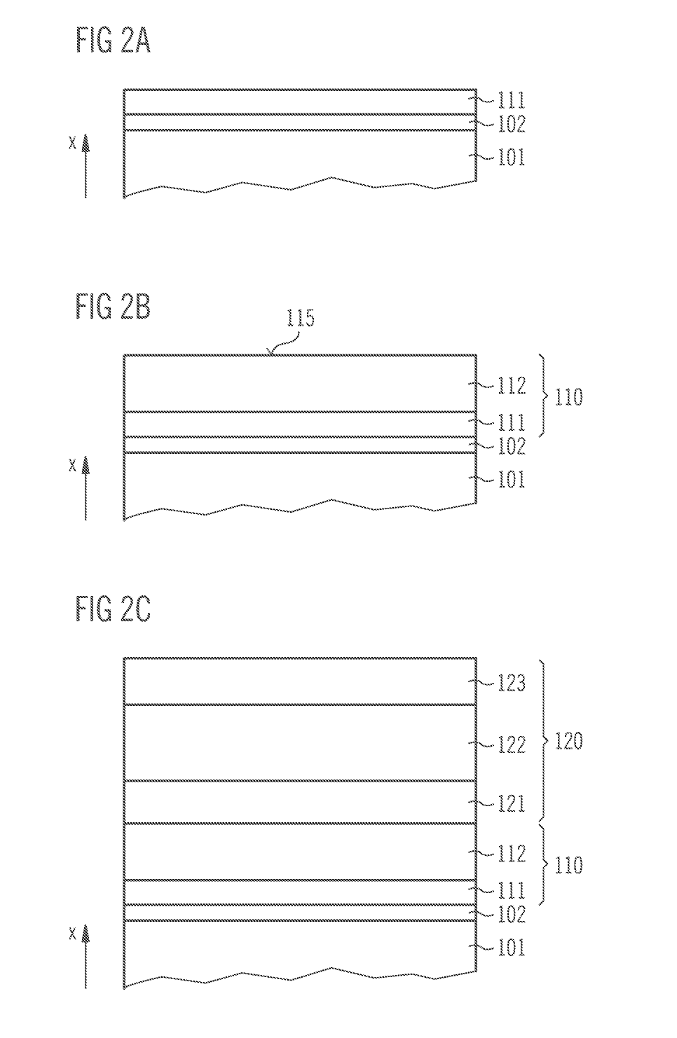

FIG. 2A schematically shows a first production step for producing the arrangement 100. In the X-direction, the passivation layer 102 is deposited onto the transparent substrate 101. The first transparent electrically conductive layer 111 is deposited onto the passivation layer 102. In a further exemplary embodiment, the first transparent electrically conductive layer 111 is deposited directly onto the transparent substrate 101 without the passivation layer 102 being arranged between the first transparent electrically conductive layer 111 and the transparent substrate 101, such that the first transparent electrically conductive layer 111 and the transparent substrate 101 touch each other.

The first transparent electrically conductive layer is deposited by a deposition sputtering method, for example. The properties of the first transparent electrically conductive layer 111, in particular with regard to surface structurability, optical transmissivity or electrical conductivity, are dependent on deposition parameters during the deposition sputtering method. Parameters on which the properties of the first transparent electrically conductive layer are dependent comprise at least one of substrate temperature, power density, oxygen partial pressure and process pressure.

The first transparent electrically conductive layer 111 is deposited with parameters with which conventionally desired properties of a front electrode cannot be produced. In one exemplary embodiment, the first transparent electrically conductive layer 111 is deposited at a substrate temperature of 250° C.±10% to 350° C.±10%. The first transparent electrically conductive layer 111 is deposited at a power density relative to the erosion area of 0.1 watt/square centimeter±10% to 100 watts/square centimeter±10%, in particular at a power density of 0.5 watt/square centimeter±10% to 5 watts/square centimeter±10%. The first transparent electrically conductive layer 111 is deposited at an oxygen partial pressure of 1×10⁻⁶ millibar±10% to 5×10 millibar±10%. The first transparent electrically conductive layer 111 is deposited at a process pressure of 1×10⁻³ millibar±10% to 50×10⁻³ millibar±10%.

The first transparent electrically conductive layer 111 is embodied as a support for the second transparent electrically conductive layer 112. By virtue of the transparent electrically conductive layer 111, the second transparent electrically conductive layer 112, which is deposited subsequently, can be deposited with different deposition parameters than if the transparent electrically conductive layer 110 merely comprises the second transparent electrically conductive layer 112 as sole layer.

FIG. 2B shows a step during production in which the second transparent electrically conductive layer 112 was deposited onto the first transparent electrically conductive layer 111 in the X-direction. The second transparent electrically conductive layer 112 is deposited directly onto the first transparent electrically conductive layer 111, such that the first and second transparent electrically conductive layers in each case touch each other.

The second transparent electrically conductive layer 112 is deposited with deposition parameters of the deposition sputtering method which are at least partly different than the deposition parameters of the first transparent electrically conductive layer 111. The second transparent electrically conductive layer 112 is deposited with parameters such that primarily a particularly good optical transmissivity and electrical conductivity of the second transparent electrically conductive layer 112 are realized. By virtue of the fact that the second transparent electrically conductive layer 112 is deposited onto the first transparent electrically conductive layer 111, the second transparent electrically conductive layer 112 additionally has a comparatively good surface structurability, even though the deposition parameters are primarily optimized toward a particularly good optical transmissivity and electrical conductivity.

By way of example, the second transparent electrically conductive layer 112 is deposited at a substrate temperature of 300±10% to 450° C.±10%. In particular, the second transparent electrically conductive layer 112 is deposited at a higher substrate temperature than the first transparent electrically conductive layer 111. The separation with regard to the respective substrate temperature of the first and second transparent electrically conductive layers is as great as possible, such that it is possible to realize the greatest possible differences in the properties of the layers. By way of example, the temperatures have a difference of between 50° C. and 200° C.

The second transparent electrically conductive layer 112 is deposited at a power density relative to the erosion area of 0.1 watt/square centimeter±10% to 100 watts/square centimeter±10%, in particular at a power density of 2 watts/square centimeter±10% to 20 watts/square centimeter±10%. The second transparent electrically conductive layer 112 is deposited at an oxygen partial pressure of 1×10⁻⁶ millibar±10% to 5×10⁻⁵ millibar±10%. The second transparent electrically conductive layer 111 is deposited at a process pressure of 1×10⁻³ millibar±10% to 50×10⁻³ millibar±10%.

The first transparent electrically conductive layer 111 is deposited with parameters such that the first transparent electrically conductive layer 111 has different properties with regard to the surface structurability taken by itself alone than the second transparent electrically conductive layer 112 taken by itself alone.

As a result of the direct deposition of the second transparent electrically conductive layer 112 onto the first transparent electrically conductive layer 111, thus forming the transparent electrically conductive layer 110, which can be used as a front electrode for a photoelectric arrangement, the second transparent electrically conductive layer 112 can be deposited in a manner optimized toward electrical conductivity and optical transmissivity. Moreover, the second transparent electrically conductive layer 112 forms a comparatively good surface structurability because it has the first transparent electrically conductive layer 111 as the foundation. It is thus possible to form a transparent electrically conductive layer 110 which has particularly good properties both with regard to the surface structurability and with regard to the electrical conductivity and optical transmissivity.

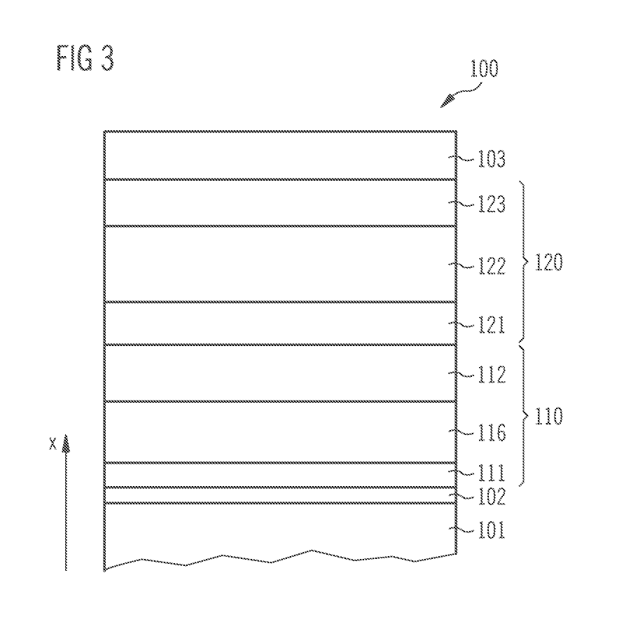

In a further embodiment, after the deposition of the first transparent electrically conductive layer 111 and before the deposition of the second transparent electrically conductive layer 112, one or a plurality of further transparent electrically conductive layers are deposited, such that the transparent electrically conductive layer 110 is formed with three or more electrically conductive layers 110, as explained in conjunction with FIG. 3.

FIG. 2C shows that the photoelectric device 120 was deposited onto the transparent electrically conductive layer 110 starting with the p-doped layer 121. Before the deposition of the photoelectric device 120 and after the deposition of the second transparent electrically conductive layer 112, the surface 115 is structured in an etching step. By way of example, a rough texture for scattering incident radiation during operation is formed on the surface 115 by means of dilute hydrochloric acid. By virtue of the fact that the second transparent electrically conductive layer 112 was deposited directly onto the first transparent electrically conductive layer 111 and the crystallinity, orientation and termination are formed depending on the first electrically conductive layer 111, it is possible to form a relatively homogeneous rough texture on the surface by means of the etching.

Both the rear-side contact 103 and a further photoelectric device, or further layers, for example a reflection layer, can be deposited onto the n-doped layer 123 of the photoelectric device 120.

The arrangement 100 comprising the photoelectric device 120 can be used in solar modules which are used, for example, on transparent substrates of approximately half a square meter to approximately 25 square meters, but also smaller or larger, in particular on transparent substrates of approximately 1.8 square meters to approximately 5.7 square meters, as so-called thin-film solar modules. Flexible substrates can have a width of up to approximately 4.5 meters, in particular a width of approximately 0.6 meter.

Two or more arrangements 100 can be electrically connected in series. Particularly with regard to the first and second transparent electrically conductive layers on a relatively large area, for example of approximately 5 square meters, the surface 115 can be structured with relatively good homogeneity over the entire area by etching.

FIG. 3 shows a further embodiment of the arrangement 100. In contrast to the embodiment explained in conjunction with FIG. 1, the transparent electrically conductive layer 110 comprises a third transparent electrically conductive layer 116.

The third transparent electrically conductive layer 116 is arranged between the first transparent electrically conductive layer 111 and the second transparent electrically conductive layer 112. In a further embodiment, the transparent electrically conductive layer 110 comprises one or a plurality of further transparent electrically conductive layers (not shown) arranged between the first transparent electrically conductive layer 111 and the second transparent electrically conductive layer 112.

The third transparent electrically conductive layer 116 has in the X-direction a gradient with regard to the properties, for example the crystallinity and/or the orientation, between the properties of the first transparent electrically conductive layer 111 and the second transparent electrically conductive layer 112.

During the production of the transparent electrically conductive layer 110, firstly the first transparent electrically conductive layer 111 is deposited with first deposition parameters. When the process for depositing the first transparent electrically conductive layer 111 has been ended, the deposition parameters are changed to the second deposition parameters, with which the second transparent electrically conductive layer 112 is deposited. During the change of the deposition parameters, the third transparent electrically conductive layer 116 is deposited. The third transparent electrically conductive layer 116 is deposited with changing deposition parameters.

1. A device, comprising:
a transparent substrate:
a transparent electrically conductive layer overlying the substrate, wherein the transparent electrically conductive layer comprises:
a first transparent electrically conductive layer,
a second transparent electrically conductive layer.

2. The device as claimed in claim 1, wherein the first transparent electrically conductive layer and the second transparent electrically conductive layer each have at least one property, wherein the at least one property of the at least one second transparent electrically conductive layer is dependent on the at least one property of the first transparent electrically conductive layer (111).

3. The device as claimed in claim 2, wherein the at least one property in each case comprises one or more of crystallinity, orientation and termination of the respective layer.

4. The device as claimed in claim 1, wherein the first transparent electrically conductive layer has a thickness of between 30 nanometers±10% and 400 nanometers±10%.

5. The device as claimed in claim 4, wherein the second transparent electrically conductive layer has a thickness of more than 200 nanometers.

6. An optical device, comprising:
a device as claimed in claim 5,
a photoelectric device for converting radiation energy into electrical energy on the transparent electrically conductive layer.

7. A method for producing a transparent electrode on a transparent substrate, the method comprising
depositing a first transparent electrically conductive layer onto the transparent substrate, the first conductive layer having a property; and
depositing a second transparent electrically conductive layer onto the first transparent electrically conductive layer, the second conductive layer having a property, wherein the property of the second transparent electrically conductive layer is dependent on the property of the first transparent electrically conductive layer.

8. The method as claimed in claim 7, wherein the property of the first and second conductive layer comprises crystallinity, orientation or termination of the respective layer.

9. The method as claimed in claim 7, wherein depositing the first transparent electrically conductive layer is deposited at a first substrate temperature; and the second transparent electrically conductive layer is deposited at a second substrate temperature, wherein the first substrate temperature is less than the second substrate temperature.

10. The method as claimed in claim 7, wherein the first transparent electrically conductive layer is deposited at a first power density and depositing the second transparent electrically conductive layer is deposited at a second power density, wherein the first power density is less than the second power density.
